(19) United States
(12) Patent Application Publication
(10) Pub. No.: US 2025/0322860 A1
(43) Pub. Date: Oct. 16, 2025

(54) NOVEL SPIN-ORBIT TORQUE MAGNETIC-RAM HAVING SPIN DIFFUSION BARRIER LAYERS

(71) Applicants: Yimin Guo, San Jpse, CA (US); Rongfu Xiao, Dublin, CA (US); Jun Chen, Fremont, CA (US)

(72) Inventors: Yimin Guo, San Jose, CA (US); Rongfu Xiao, Dublin, CA (US); Jun Chen, Fremont, CA (US)

(21) Appl. No.: 18/634,932

(22) Filed: Apr. 13, 2024

(51) Int. Cl. G11C 11/16; H01F 10/32; H10B 61/00; H10N 50/10; H10N 50/85; H10N 52/85

(52) U.S. Cl. CPC G11C 11/161; G11C 11/1673; G11C 11/1675; H01F 10/3272; H10B 61/22; H10N 50/10; H10N 50/85; H10N 52/85

(57) ABSTRACT

A spin Hall effect magnetoresistive memory device comprises a three-terminal magnetoresistive memory cell consisting of an MTJ stack, a spin diffusion barrier layer, a magnetic functional layer with its magnetization either anti-parallel or parallel to the magnetic recording layer magnetization in the MTJ stack, and an SHE-metal layer. Bi-directional recording current along the SHE metal layer directly switches the magnetization of the magnetic functional layer and indirectly switches the magnetization of the magnetic recording layer through the coupling between the magnetic functional layer and the magnetic recording layer.

### BACKGROUND OF THE INVENTION

### 1. Field of the Invention

This invention relates generally to a three-terminal spin-orbit torque magnetic-random-access memory (MRAM) element having a magnetic functional layer and a spin diffusion barrier layer.

### 2. Description of the Related Art

In recent years, magnetic random access memories (hereinafter referred to as MRAMs) using the magnetoresistive effect of ferromagnetic tunnel junctions (also called MTJs) have been drawing increasing attention as the next-generation solid-state nonvolatile memories that can also cope with high-speed reading and writing. A ferromagnetic tunnel junction has a three-layer stack structure formed by stacking a recording layer having a changeable magnetization direction, an insulating tunnel barrier layer, and a fixed layer that is located on the opposite side from the recording layer and maintains a predetermined magnetization direction. Corresponding to the parallel and anti-parallel magnetic states between the recording layer magnetization and the reference layer magnetization, the magnetic memory element has low and high electrical resistance states, respectively. Accordingly, a detection of the resistance allows a magnetoresistive element to provide information stored in the magnetic memory device.

Typically, MRAM devices are classified by different write methods. A traditional MRAM is a magnetic field-switched MRAM utilizing electric line currents to generate magnetic fields and switch the magnetization direction of the recording layer in a magnetoresistive element at their cross-point location during the programming write. A spin-transfer torque (or STT)-MRAM has a different write method utilizing electrons' spin momentum transfer. Specifically, the angular momentum of the spin-polarized electrons is transmitted to the electrons in the magnetic material serving as the magnetic recording layer. According to this method, the magnetization direction of a recording layer is reversed by applying a spin-polarized current to the magnetoresistive element. As the volume of the magnetic layer forming the recording layer is smaller, the injected spin-polarized current to write or switch can be also smaller.

To record information or change resistance state, typically a recording current is provided by its CMOS transistor to flow in the stacked direction of the magnetoresistive element, which is hereinafter referred to as a “vertical spin-transfer method.” Generally, constant-voltage recording is performed when recording is performed in a memory device accompanied by a resistance change. In a STT-MRAM, the majority of the applied voltage is acting on a thin oxide layer (tunnel barrier layer) which is about 10 angstroms thick, and, if an excessive voltage is applied, the tunnel barrier breaks down. More, even when the tunnel barrier does not immediately break down, if recording operations are repeated, the element may still become nonfunctional such that the resistance value changes (decreases) and information readout errors increase, making the element un-recordable. Furthermore, recording is not performed unless a sufficient voltage or sufficient spin current is applied. Accordingly, problems with insufficient recording arise before possible tunnel barrier breaks down.

Reading STT MRAM involves applying a voltage to the MTJ stack to discover whether the MTJ element states at high resistance or low. However, a relatively high voltage needs to be applied to the MTJ to correctly determine whether its resistance is high or low, and the current passed at this voltage leaves little difference between the read-voltage and the write-voltage. Any fluctuation in the electrical characteristics of individual MTJs at advanced technology nodes could cause what was intended as a read-current, to have the effect of a write-current, thus reversing the direction of magnetization of the recording layer in MTJ.

It has been known that a spin current can, alternatively, be generated in non-magnetic transition metal material by a so-called Spin Hall Effect (SHE), in which spin-orbit coupling causes electrons with different spins to deflect in different directions yielding a pure spin current transverse to an applied charge current. Spin-orbit torque (SOT) refers to the torque exerted on a magnetic layer due to the spin-orbit coupling of electrons when a charge current passes through a material with strong spin-orbit interaction. The Giant Spin Hall Effect (GSHE), which involves the generation of substantial spin currents perpendicular to the direction of charge current flow in certain high-Z metals (such as Pt, β-Ta, β-W, and doped Cu), offers a promising solution to address voltage, current scaling, and reliability challenges in spin torque transfer MRAM. This phenomenon is driven by bulk spin-orbit coupling within the heavy metal layer, leading to the generation of spin-orbit torques. Specifically, in these heavy metals, bulk spin-orbit coupling facilitates the conversion of an applied charge current into a transverse spin current, which in turn imparts spin-orbit torque on adjacent magnetic layers.

Due to the thermal stability requirement, the recording layer is typically is patterned into an oval or ellipse like shape with an aspect ratio larger than 1.0 for a desired uni-axial shape anisotropy. A spin orbit torque coming from the spin Hall effect has to be large enough to overcome a large energy barrier to switch the magnetization of the recording layer from one energy minimum state to the other energy minimum state, depending upon the spin Hall current direction.

Thus, it is desirable to provide an SOT-MRAM structure having much reduced switching energy barrier for recording while providing high enough thermal energy barrier for good data retention.

### BRIEF SUMMARY OF THE PRESENT INVENTION

The present invention comprises a three terminal magnetoresistive element having a magnetic functional layer which is magnetically coupled to a recording layer of an MTJ junction stack through a spin diffusion barrier layer and a giant-SHE metal layer immediately adjacent to the magnetic functional layer to produce a direct spin orbit torque-induced switching of magnetization in the magnetic functional layer and an indirect switching of the recording layer magnetization, with read-out using a magnetic tunnel junction with a large magnetoresistance.

An exemplary embodiment includes a structure of a three terminal spin-orbit-torque magnetoresistive memory including a bit line positioned adjacent to selected ones of the plurality of magnetoresistive memory elements to supply a reading current across the magnetoresistive element stack and to supply a bi-directional spin Hall effect recording current, and accordingly to directly switch the magnetization of the magnetic functional layer and indirectly switch the magnetization of the recording layer through a magnetic coupling. The primary role of the spin diffusion barrier layer is to confine spin-polarized electrons induced by the spin Hall effect, or polarized spin diffusion, within the magnetic functional layer's region, thereby preventing their undesired diffusion into the magnetic free layer (the recording layer). This confinement is essential for maintaining a high density of polarized spin accumulation, or high spin orbit torque, within the magnetic functional layer, while simultaneously inhibiting spin orbit torque on the magnetic free layer. This leads to direct spin orbit torque-induced switching of magnetization in the magnetic coupling layer and indirect switching of the recording layer magnetization. In this mode, the energy barrier for switching is significantly smaller than the thermal energy barrier, allowing the recording layer's magnetization to be readily switched or reversed in alignment with the current direction along the spin Hall effect-metal layer by applying a low write current.

The drawings are schematic or conceptual, and the relationships between the thickness and width of portions, the proportional coefficients of sizes among portions, etc., are not necessarily the same as the actual values thereof.

### BRIEF DESCRIPTION OF THE DRAWINGS

FIG. 1 is a cross-section of one memory cell in a three terminal SOT MRAM array;

FIG. 2(A, B) are schematics of using spin Hall effect writing current to directly reverse the magnetic functional layer magnetization to the direction in accordance with a direction of a current along the SHE-metal and reverse the recording layer magnetization through an anti-parallel coupling between the magnetic functional layer and the recording layer;

FIG. 3(A, B) are schematics of using spin Hall effect writing current to directly reverse the magnetic functional layer magnetization to the direction in accordance with a direction of a current along the SHE-metal and reverse the magnetic recording layer magnetization through a parallel coupling between the magnetic functional layer and the magnetic recording layer;

FIG. 4 is a schematic cross-section of one recording layer having either a synthetic antiferromagnetic structure or a synthetic ferrimagnetic structure.

### DETAILED DESCRIPTION OF THE INVENTION

In general, according to each embodiment, there is provided a three terminal SOT magnetoresistive memory cell comprising:
an SHE metal layer provided on a surface of a substrate;
a magnetic functional layer provided on the top of the SHE metal layer, comprising a ferromagnetic material, and having a magnetic anisotropy and a variable magnetization direction;
a spin diffusion barrier layer provided on the top surface of the magnetic functional layer, comprising at least one layer of spin diffusion barrier material with a spin diffusion length of less than 0.6 nm;
a magnetic recording layer provided on the top surface of the spin diffusion barrier layer, having a magnetic anisotropy and a variable magnetization direction;
a tunnel barrier layer provided on the top surface of the recording layer;
a magnetic reference layer provided on the top surface of the tunnel barrier layer, and having an invariable magnetization direction;
a cap layer provided on the top surface of the magnetic reference layer as an upper electric electrode;
a first bottom electrode provided on a first side of the SHE metal layer and electrically connected to the SHE metal layer;
a second bottom electrode provided on a second side of the SHE metal layer and electrically connected to the SHE metal layer;
a bit line provided on the top surface of the cap layer; and
two CMOS transistors coupled the plurality of magnetoresistive memory elements through the two bottom electrodes.

There is further provided circuitry connected to the bit line, and two select transistors of each magnetoresistive memory cell.

Spin Hall effect consists of the appearance of spin accumulation on the lateral surfaces of an electric current-carrying sample, the signs of the spin directions being opposite on the opposing boundaries. When the current direction is reversed, the directions of spin orientation are also reversed. The origin of SHE is in the spin-orbit interaction, which leads to the coupling of spin and charge currents: an electrical current induces a transverse spin current (a flow of spins) and vice versa. In a giant spin Hall effect (GSHE), very large spin currents transverse to the charge current direction in specific high-Z metal material (such as Pt, β-Ta, β-W, PtCu, doped β-W, PtHf) layer underneath a recording layer may switch the magnetization directions. A polarization ratio in the spin current depends on not only material but also its thickness. Typically, the spin current polarization ratio reached the maximum at a thickness of ˜2 nm. A thin SHE metal layer made of beta-phase tungsten provides a higher spin polarization ratio and a higher resistivity than Ta or Pt SHE layer.

An exemplary embodiment includes a structure of a three terminal SHE spin-orbit-torque magnetoresistive memory including a bit line positioned adjacent to selected ones of the plurality of magnetoresistive memory elements to supply a reading current across the magnetoresistive element stack and to supply a bi-directional spin Hall effect recording current, and accordingly to directly switch the magnetization of the magnetic functional layer and indirectly switch the magnetization of the magnetic recording layer through a magnetic coupling. The spin diffusion barrier layer is made of nonmagnetic material having a very small spin diffusion length. The magnetic functional layer is made of ferromagnetic material having a very low damping constant, a polarized spin-Hall current flowing perpendicularly to the magnetic functional layer applies a spin orbit torque mainly on the magnetic functional layer and causes a switching of the magnetization. Since such a switch energy barrier is much smaller than the thermal energy barrier, the magnetization of a recording layer can be readily switched or reversed to the direction in accordance with a direction of a current along the SHE metal layer by applying a low write current.

The following detailed descriptions are merely illustrative in nature and are not intended to limit the embodiments of the subject matter or the application and uses of such embodiments. Any implementation described herein as exemplary is not necessarily to be construed as preferred or advantageous over other implementations. Furthermore, there is no intention to be bound by any expressed or implied theory presented in the preceding technical field, background, brief summary, or the following detailed description.

FIG. 1 is a cross-sectional view of a three terminal magnetoresistive memory cell 30 in an SOT-MRAM array having an SHE induced spin orbit torque switching. The magnetoresistive memory cell 30 is configured by a bit line 18, a cap layer 17, a magnetic reference layer 16, a tunnel barrier 15, a magnetic recording layer 14, a spin diffusion barrier layer 13, a magnetic functional layer 12, an SHE metal layer 11, a dielectric substrate 10, and a dielectric layer 101. Both the magnetic functional layer and the recording layer are magnetic layers, and have uniaxial anisotropies and variable magnetizations in a film pane. The magnetic reference layer has a fixed magnetization in a film plane. The magnetic reference layer can be a synthetic antiferromagnetic structure having a nonmagnetic metal layer sandwiched by two ferromagnetic layers which have an anti-parallel coupling. Further, an antiferromagnetic (AFM) pinning layer can be added on top of the magnetic reference layer to fix the magnetic reference layer magnetization direction.

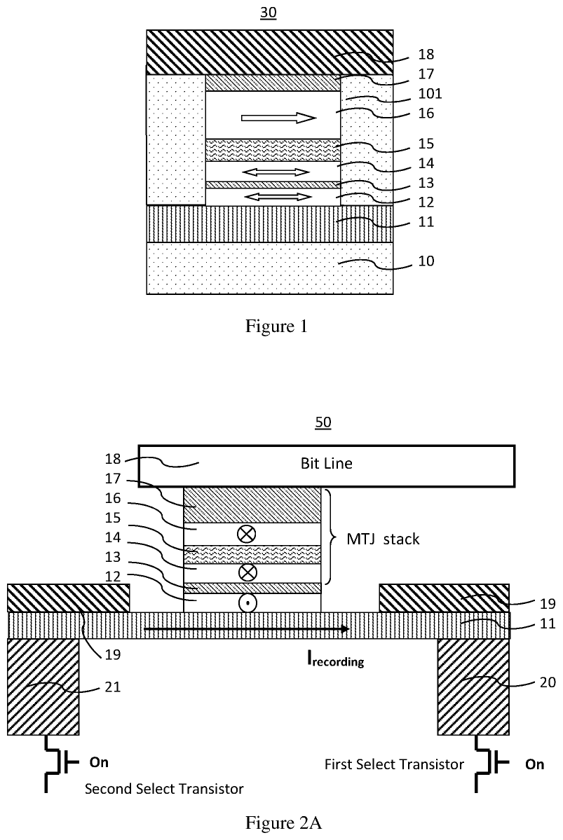

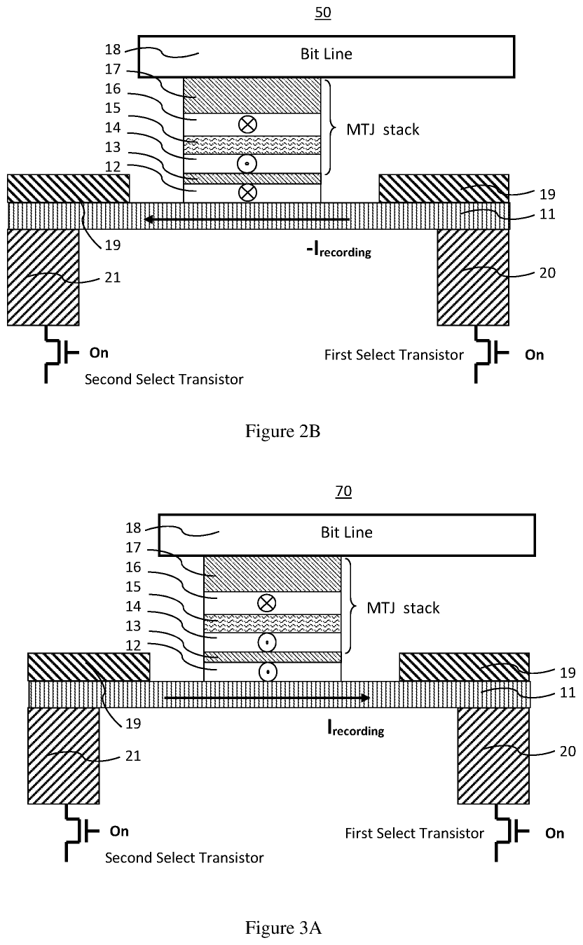

As a first embodiment, FIGS. 2A and 2B show a magnetoresistive element 50 illustrating the methods of operating a spin-orbit-torque magnetoresistive memory: an SHE spin orbit torque current driven recording layer magnetization to two directions in accordance with directions of an SHE current along the SHE-metal layer, respectively. A circuitry, which is not shown here, is coupled to two select transistors for providing a bi-directional current in the SHE metal layer between a first bottom electrode and a second electrode. The magnetoresistive element 50 comprises: a bit line 18, an MTJ stack comprising a cap layer 17, a magnetic reference layer 16, a tunnel barrier 15 and a magnetic recording layer 14, a spin diffusion barrier layer 13, a magnetic functional layer 12, an SHE metal layer 11, a bottom electrode conductivity enhancement layer 19, a first VIA 20 connecting a first bottom electrode and a first select transistor, a second VIA 21 connecting a second bottom electrode and a first select transistor. The SHE metal layer is made by a high-Z metal, such as Pt, β-Ta, β-W, Pt, doped Cu, having a thickness in a range between 1.5 nm and 6 nm. The magnetic functional layer and the magnetic recording layer are magnetically anti-parallel coupled with each other through the spin diffusion barrier layer. The spin diffusion barrier layer 13 is made of a material having a very short spin diffusion length, selected from non-magnetic light element insulator, or light element oxides or nitrides, such as MgO, SiO₂, AlOₓ, MgN, etc. Antiferromagnetic oxides, such as Nickel Oxide (NiO), Hematite (α-Fe₂O₃), Cobalt Oxide (CoO), Chromium Oxide (Cr₂O₃), or Vanadium Oxide (VO₂), typically conduct angular momentum and exhibit large spin diffusion lengths. As a result, they are not ideal candidates for use as spin diffusion barrier layer.

For instance, a 0.5 nm thick crystal MgO layer can serve as a highly efficient spin diffusion barrier since a crystal MgO has a spin diffusion length of less than 0.2 nm and an excellent spin reflection, resulting in a significant accumulation of polarized spin within the magnetic functional layer situated directly adjacent to the SHE metal layer. Moreover, an additional thin layer of iron (Fe) may be inserted between the spin diffusion barrier layer, MgO, and either the magnetic recording layer or the magnetic functional layer. This insertion serves to introduce antiferromagnetic coupling between the magnetic recording layer and the magnetic functional layer.

It's essential to understand that in this synthetic structure, comprising a spin diffusion barrier layer nestled between two antiferromagnetically coupled magnetic layers (the magnetic functional layer and the magnetic recording layer), when the write current traverses the SHE metal layer, a perpendicular polarized spin current is channeled into the adjacent magnetic functional layer, however, it is blocked from entering the recording layer by the spin diffusion barrier layer, effectively obstructing its passage. Put differently, spin-orbit torque predominantly affects only one of these layers, namely the magnetic functional layer.

When the spin electron density or spin orbit torque reaches a sufficient magnitude, the magnetization of the magnetic functional layer can be switched due to the influence of the spin orbit torque, consequently leading to a corresponding switch in the magnetization of the recording layer due to the antiferromagnetic coupling field and demag field. This rotational movement of the recording layer's magnetization counteracts a portion of the demagnetization charge or field originating from the magnetic functional layer. As a result, the energy barrier for switching becomes much smaller than its thermal energy barrier.

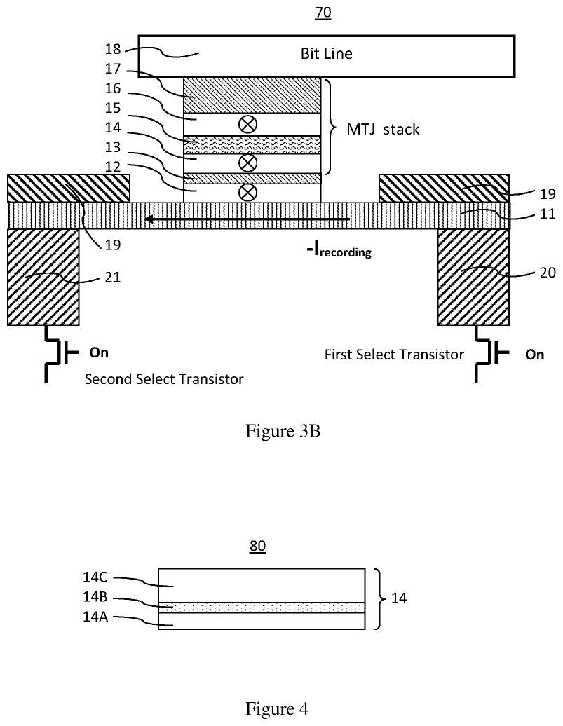

As a second embodiment, FIGS. 3A and 3B show magnetoresistive element 70 illustrating the methods of operating a spin-orbit-torque magnetoresistive memory: an SHE induced spin orbit torque current driven recording layer magnetization to two directions in accordance with directions of an SHE current along the SHE-metal layer, respectively. A circuitry, which is not shown here, is coupled to two select transistors for providing a bi-directional current in the SHE metal layer between a first bottom electrode and a second electrode. The magnetoresistive element 50 comprises: a bit line 18, an MTJ stack comprising a cap layer 17, a magnetic reference layer 16, a tunnel barrier 15 and a magnetic recording layer 14, a spin diffusion barrier layer 13, a magnetic functional layer 12, an SHE metal layer 11, a bottom electrode conductivity enhancement layer 19, a first VIA 20 connecting a first bottom electrode and a first select transistor, a second VIA 21 connecting a second bottom electrode and a first select transistor. The SHE metal layer is made by a high-Z metal, such as Pt, β-Ta, β-W, Pt, doped Cu, having a thickness in a range between 1.5 nm and 6 nm. The magnetic functional layer and the magnetic recording layer are magnetically parallel coupled with each other through the spin diffusion barrier layer. The spin diffusion barrier layer is made of an amorphous phase metal, amorphous phase metal alloy, or amorphous phase non-metal material, comprising at least one element selected from the group consisting of Ta, W, Hf, Zr, Nb, Mo, Ti, V, Cr, B, Al, Si, C, P, and S, especially amorphous Hf, amorphous Ta, etc., or made of a thin layer of oxide, nitride, or oxynitride, comprising a light element selected from the group consisting of Si, Mg, Be, Ca, Na, Zn, Li, K, B, and Al, etc. For instance, a 0.7 nm amorphous Hf layer can serve as a highly efficient spin diffusion barrier since amorphous Hf has a spin diffusion length of about 0.3 nm, resulting in a significant accumulation of polarized spin within the magnetic functional layer situated directly adjacent to the SHE metal layer. Moreover, this spin diffusion barrier layer serves to introduce ferromagnetic coupling between the recording layer and the magnetic functional layer. The thickness of the spin diffusion barrier layer is less than 2.0 nm, preferred to be less than 1.0 nm.

It's essential to understand that in this structure, comprising a spin diffusion barrier layer nestled between two magnetically coupled magnetic layers (the magnetic functional layer and the magnetic recording layer), when the write current traverses the SHE metal layer, a perpendicular polarized spin current is channeled into the adjacent magnetic functional layer, however, it is blocked from entering the recording layer by the spin diffusion barrier layer, effectively obstructing its passage. Put differently, spin-orbit torque predominantly affects only one of these layers, namely the magnetic functional layer. When the spin electron density or spin orbit torque reaches a sufficient magnitude, the magnetization of the magnetic functional layer can be switched due to the influence of the spin orbit torque, consequently leading to a corresponding switch in the magnetization of the recording layer due to the magnetic coupling field.

FIG. 4 is a cross-sectional view of a recording layer having a synthetic antiferromagnetic structure, or a synthetic ferrimagnetic structure. The synthetic structure 80 is configured by a first recording sub-layer 14A, a synthetic coupling layer 14B, a second recording sub-layer 14C. Both the first and second recording sub-layers are ferromagnetic layers and have variable magnetizations. The synthetic coupling layer 14B induces antiferromagnetic coupling between the first and second recording sub-layers, leading to anti-parallel alignment of their magnetic moments. Antiferromagnetic coupling layers are used to stabilize the magnetization direction of the ferromagnetic layers and improve their thermal stability. In a synthetic antiferromagnetic structure, the two ferromagnetic layers, 14A and 14C, possess nearly equal magnetic moments. Conversely, in a synthetic ferrimagnetic structure, the magnetic moments of the two ferromagnetic layers, 14A and 14C, are unequal. The properties of synthetic structures can be tailored by adjusting parameters such as the thickness and composition of the ferromagnetic layers, as well as the coupling between them. Typically, the synthetic coupling layer 14B consists of a single layer composed of materials like Ru, Rh, Ir, Cr, or a bilayer configuration such as Ru/Ta, Ru/W, and so forth. The magnetic functional layer may also comprise a synthetic antiferromagnetic structure, or a synthetic ferrimagnetic structure. When a recording layer with a synthetic ferrimagnetic structure and a magnetic functional layer are parallel-coupled across a spin diffusion barrier layer, they may assemble into a synthetic antiferromagnetic structure. Similarly, parallel-coupling a magnetic functional layer with a synthetic ferrimagnetic structure and a recording layer across a spin diffusion barrier layer can lead to the formation of a synthetic antiferromagnetic structure.

As depicted in the figures above, while the magnetic functional layer, the magnetic recording layer, and the magnetic reference layer typically exhibit in-plane magnetic anisotropies and magnetizations, they can also be designed and engineered to possess perpendicular magnetic anisotropies and perpendicular magnetizations. Moreover, the effectiveness of spin diffusion blocking can be further enhanced by employing multiple spin diffusion barrier layers. In such cases, ferromagnetic material layers can be inserted between the spin diffusion barrier layers to provide separation and magnetic coupling.

While certain embodiments have been described above, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A spin-orbit torque magnetoresistive memory device, comprising:
an SHE metal layer provided on a surface of a substrate;
a magnetic functional layer provided on the top of the SHE metal layer, said magnetic functional layer comprising a ferromagnetic material;
a spin diffusion barrier layer provided on the top surface of the magnetic functional layer, said spin diffusion barrier layer comprising at least one layer of spin diffusion barrier material with a spin diffusion length of less than 0.6 nm;
a magnetic recording layer provided on the top surface of the spin diffusion barrier layer;
a tunnel barrier layer provided on the top surface of the magnetic recording layer;
a magnetic reference layer provided on the top surface of the tunnel barrier layer;
a cap layer provided on the top surface of the magnetic reference layer as an upper electric electrode;
a first bottom electrode provided on a first side of the SHE metal layer and electrically connected to the SHE metal layer;
a second bottom electrode provided on a second side of the SHE metal layer and electrically connected to the SHE metal layer; and
a bit line provided on the top surface of the cap layer,
wherein said magnetic functional layer, said spin diffusion barrier layer, said magnetic recording layer, said tunnel barrier layer, said magnetic reference layer, and said cap layer, form a composite MTJ stack.

2. The spin-orbit torque magnetoresistive memory device of claim 1, wherein said SHE metal layer comprises a doped or non-doped beta-phase high-Z element layer comprising at least one element selected from the group consisting of W, Ta, and Hf, doping agent is selected from P, S, Si, Al, and rare earth elements.

3. The spin-orbit torque magnetoresistive memory device of claim 1, wherein said SHE metal layer is made of a doped or non-doped metal layer comprising at least one element selected from the group consisting of Pt, Pd, Nb, Mo, Ru, Re, Os, Ir, Au, Cu, TI, Pb, Bi, doping agent is selected from W, Ta, Hf, Ni, Fe, Co, Cr, Mn, V, Y and rare earth elements.

4. The spin-orbit torque magnetoresistive memory device of claim 1, wherein the thickness of said SHE metal layer is more than 1.5 nm and less than 10 nm.

5. The spin-orbit torque magnetoresistive memory device of claim 1, further comprising two select transistors connected to the two bottom electrodes, the two select transistors and the bit line being connected to an external control circuitry, wherein the external control circuitry facilitates supplying a reading current across the composite MTJ stack and the two bottom electrodes, and supplying a bi-directional recording current across the two bottom electrodes and along the SHE metal layer, the bi-directional recording current generating a spin accumulation at the interface between the SHE metal layer and the magnetic functional layer, the spin accumulation diffusing into the magnetic functional layer and directly switching the magnetization of the magnetic functional layer and indirectly switching the magnetization of the magnetic recording layer through a magnetic coupling between the magnetic functional layer and the magnetic recording layer.

6. The spin-orbit torque magnetoresistive memory device of claim 1, wherein said magnetic recording layer comprises a multilayer having either a synthetic antiferromagnetic structure or a synthetic ferrimagnetic structure.

7. The spin-orbit torque magnetoresistive memory device of claim 1, wherein said magnetic functional layer comprises a multilayer having either a synthetic antiferromagnetic structure or a synthetic ferrimagnetic structure.

8. The spin-orbit torque magnetoresistive memory device of claim 1, wherein the magnetization of said magnetic recording layer is anti-parallelly coupled to the magnetization of said magnetic functional layer across said spin diffusion barrier layer.

9. The spin-orbit torque magnetoresistive memory device of claim 1, wherein the magnetization of said magnetic recording layer is parallelly coupled to the magnetization of said magnetic functional layer through said spin diffusion barrier layer.

10. The spin-orbit torque magnetoresistive memory device of claim 1, wherein said spin diffusion barrier material is made of an amorphous phase metal, amorphous phase metal alloy, or amorphous phase non-metal material, comprising at least one element selected from the group consisting of Ta, W, Hf, Zr, Nb, Mo, Ti, V, Cr, B, Al, Si, C, P, and S.

11. The spin-orbit torque magnetoresistive memory device of claim 1, wherein said spin diffusion barrier material is made of a light element oxide, light element nitride, or light element oxynitride, comprising at least one element selected from the group consisting of Si, Mg, Be, Ca, Na, Zn, Li, K, B, and Al.

12. The spin-orbit torque magnetoresistive memory device of claim 1, wherein said magnetic recording layer comprises a multi-layer comprising ferromagnetic sub-layers and optional nonmagnetic insertion sub-layers containing at least one element selected from Ta, Hf, Zr, Ti, Mg, Nb, W, Mo, Ru, Al, Cu, Si, and each optional nonmagnetic insertion sub-layer having a thickness less than 0.5 nm.

13. The spin-orbit torque magnetoresistive memory device of claim 1, said magnetic functional layer comprises a multi-layer comprising ferromagnetic sub-layers and optional nonmagnetic insertion sub-layers containing at least one element selected from Ta, Hf, Zr, Ti, Mg, Nb, W, Mo, Ru, Al, Cu, Si, and each optional nonmagnetic insertion sub-layer having a thickness less than 0.5 nm.

14. The spin-orbit torque magnetoresistive memory device of claim 1, wherein said magnetic recording layer is patterned into an in-plane shape having an aspect ratio between 1.2 and 5.

15. The spin-orbit torque magnetoresistive memory device of claim 1, wherein said magnetic functional layer is patterned into an in-plane shape having an aspect ratio between 1.2 and 5, and having in-plane dimensions equal to or larger than that of the magnetic recording layer.

16. The spin-orbit torque magnetoresistive memory device of claim 1, further comprising a spin diffusion enhancement layer inserted between said SHE metal layer and said magnetic functional layer, wherein said spin diffusion enhancement layer improves the efficiency of spin diffusion from the SHE metal layer to the magnetic functional layer, and comprises at least one element selected from the group consisting of Hf, Ru, Rh, Ag, Au, Ni, Co, Fe, Cu, Zn, Mn, Ti, V, Pt, Ir, Ta, W, and Pd.

17. The spin-orbit torque magnetoresistive memory device of claim 1, wherein said spin diffusion barrier layer has a thickness of less than 1.0 nm.

18. The spin-orbit torque magnetoresistive memory device of claim 1, wherein said spin diffusion barrier layer has a thickness of less than 0.6 nm.

19. The spin-orbit torque magnetoresistive memory device of claim 1, wherein said spin diffusion barrier layer comprises two layers of spin diffusion barrier materials with a spin diffusion length of less than 0.6 nm.

20. The spin-orbit torque magnetoresistive memory device of claim 1, wherein spin diffusion barrier layer comprises an MgO or MgAl₂O₄ layer, and at least one of the magnetic functional layer and the magnetic recording layer has an Fe sub-layer interfacing with the MgO or MgAl₂O₄ layer.
